(19) United States
(12) Patent Application Publication
(10) Pub. No.: US 2017/0205462 A1
(43) Pub. Date: Jul. 20, 2017

(54) POWER-ON SELF-TEST AND IN-SYSTEM TEST

(71) Applicant: Mentor Graphics Corporation, Wilsonville, OR (US)

(72) Inventors: Nilanjan Mukherjee, Wilsonville, OR (US); Subramanian Mahadevan, Portland, OR (US)

(73) Assignee: Mentor Graphics Corporation

(21) Appl. No.: 15/400,910

(22) Filed: Jan. 6, 2017

Related U.S. Application Data
(60) Provisional application No. 62/275,573, filed on Jan. 6, 2016.

(51) Int. Cl. G01R 31/3177; G01R 31/317; G11C 29/38

(52) U.S. Cl. CPC G01R 31/3177; G11C 29/38; G01R 31/31724; G01R 31/31723

(57) ABSTRACT

An integrated circuit comprises a plurality of built-in self-test circuits, a plurality of SIBs (segment insertion bits) coupled to a plurality of registers that are associated with the plurality of built-in self-test circuits, one or more storage devices, and a controller coupled to a part or a whole of an IJTAG (IEEE 1687) network and to the one or more storage devices. The plurality of SIBs and the plurality of registers form the part or the whole of the IJTAG network. The controller supplies to the part or the whole of the IJTAG network test vectors which are stored in the one or more storage devices or are received from a different source. The different source may be a tester.

### RELATED APPLICATIONS

This application claims the benefit of U.S. Provisional Patent Application No. 62/275,573, filed on Jan. 6, 2016, and naming Nilanjan Mukherjee as inventor, which application is incorporated entirely herein by reference.

FIELD OF THE DISCLOSED TECHNIQUES

The presently disclosed techniques relates to the field of circuit test technology. Various implementations of the disclosed techniques may be particularly useful for power-on self-test and in-system test.

### BACKGROUND OF THE DISCLOSED TECHNIQUES

Electronics content in vehicles is constantly growing, which enables advanced safety features, new information and entertainment services, and greater energy efficiency. In 2015, electronic systems already accounted for more than one third of new vehicle cost. All electronic circuits carry the possibility of failure. A single point of failure has immediate potential to cause hazards. A latent failure can become dangerous in conjunction with a second fault and aggregate. A common cause failure can cause several components to fail at the same time and possibly annul any redundancy measures, which has a great impact on safety of automobiles. All these types of failures need to be detected quickly.

Integrated circuits normally undergo manufacturing test before being installed in vehicles. The manufacturing test includes conventional circuit test using automatic test equipment and reliability test. To enhance safety and reliability, circuits also need to be tested in a vehicle while the vehicle is being or to be operated. This so-called in-system test includes two variations: power-on self-test and on-demand in-system test. As the names suggest, the power-on self-test run the test immediately after the circuit is powered on while the on-demand in-system test run the test on demand during the circuit is operated.

Built-in self-test circuits are built into integrated circuits allowing them to perform in-system tests. Built-in self-test circuits designed for testing logic circuitry are called logic built-in self-test circuits (LBIST) and those designed for testing memory are called memory built-in self-test circuits (MBIST). In a typical LBIST architecture, a pseudorandom pattern generator (PRPG) generates test patterns for scan chains and the circuit responses captured by the scan chains are collected in a multiple-input signature register (MISR). The final content of the MISR is a signature to be compared to a pre-calculated, or expected, signature. A typical MBIST includes a pattern generator, a MBIST controller and a response analyzer. Memories fail in a number of different ways. The three main parts—address decoder logic, memory cell array, and read/write logic—can each have flaws that cause the device to fail. Memory testing, while similar to random logic testing, focuses on testing for these memory-specific failures. A MBIST is often capable of running several algorithms.

There are some challenges to in-system tests, especially those to be used in automotive environment. For example, test runtime overhead cannot be too large considering the idle time intervals between functional operations of a circuit that can be used for testing is quite limited. While setting up a specific test can be controlled by a processor installed on-board, this configuration precludes the circuitry of the processor from being tested. Further, a state-of-the-art circuit may include many BIST circuits. It is desirable to readily configure and run various combinations of test programs.

### BRIEF SUMMARY OF THE DISCLOSED TECHNIQUES

Various aspects of the disclosed technology relate to techniques of designing circuits for power-on test, in-system test or both. In one aspect, there is an integrated circuit, comprising: a plurality of built-in self-test circuits; a plurality of SIBs (segment insertion bits) coupled to a plurality of registers associated with the plurality of built-in self-test circuits, the plurality of SIBs and the plurality of registers forming a part or a whole of an IJTAG (IEEE 1687) network; one or more storage devices; and a controller coupled to the part or the whole of the IJTAG network and to the one or more storage devices, wherein the controller supplies to the part or the whole of the IJTAG network test vectors which are stored in the one or more storage devices or are received from a different source.

The integrated circuit may further comprise: a second plurality of built-in self-test circuits; a second plurality of SIBs (segment insertion bits) coupled to a second plurality of registers associated with the second plurality of built-in self-test circuits, the second plurality of SIBs and the second plurality of registers forming a second part of the IJTAG network; second one or more storage devices; and a second controller coupled to the second part of the IJTAG network and to the second one or more storage devices, wherein the second controller supplies to the second part of the IJTAG network test vectors which are stored in the second one or more storage devices or are received from the different source.

The plurality of built-in self-test circuits comprise logic built-in self-test circuits (LBIST), memory built-in self-test circuits (MBIST) or both.

The different source is a tester. The tester may deliver the test vectors to the integrated circuit through a JTAG (IEEE 1149.1) interface of the integrated circuit.

The one or more storage devices is a read-only memory device.

The controller may comprise a finite state machine. The controller may comprise logic circuitry for generating IJTAG interface signals based on input signals. The controller may comprise logic circuitry for comparing test response data received from the IJTAG network with expected test response data stored in the one or more storage devices.

In another aspect, there are one or more non-transitory computer-readable media storing computer-executable instructions for causing one or more processors to insert circuitry into a circuit design, the circuitry comprising: a controller coupled to a part or a whole of an IJTAG network and to one or more storage devices, wherein the part or the whole of the IJTAG network comprises a plurality of SIBs and a plurality of registers associated with a plurality of built-in self-test circuits, and wherein the controller supplies to the part or the whole of the IJTAG network test vectors which are stored in the one or more storage devices or are received from a different source.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclose techniques. Thus, for example, those skilled in the art will recognize that the disclose techniques may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a block diagram of circuit architecture for in-system test according to various embodiments of the disclosed technology.

FIG. 2 illustrates an example of a block diagram of the controller 110 according to some embodiments of the disclosed technology.

FIG. 3 illustrates another example of a block diagram of the controller 110 according to some embodiments of the disclosed technology.

FIG. 4 illustrates an example of a block diagram of the analysis circuitry according to various embodiments of the disclosed technology.

FIG. 5A illustrates an example of a block diagram of a SIB (segment insertion bit); FIG. 5B illustrates an example of a hierarchical SIBs network.

FIG. 6 illustrates an example of a design with a LBIST controller and two EDT/LBIST blocks.

FIG. 7 illustrates an example of a design with a MBIST.

FIG. 8 illustrates a programmable computer system with which various embodiments of the disclosed technology may be employed.

FIG. 9 illustrates an example of an IJTAG network comprising two controllers for two IJTAG segments test according to various embodiments of the disclosed technology.

### DETAILED DESCRIPTION OF THE DISCLOSED TECHNIQUES

Various aspects of the disclosed technology relate to techniques of designing circuits for power-on test, in-system test or both. In the following description, numerous details are set forth for the purpose of explanation. However, one of ordinary skill in the art will realize that the disclosed technology may be practiced without the use of these specific details. In other instances, well-known features have not been described in details to avoid obscuring the disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one microdevice, such as data to be used to form multiple microdevices on a single wafer.

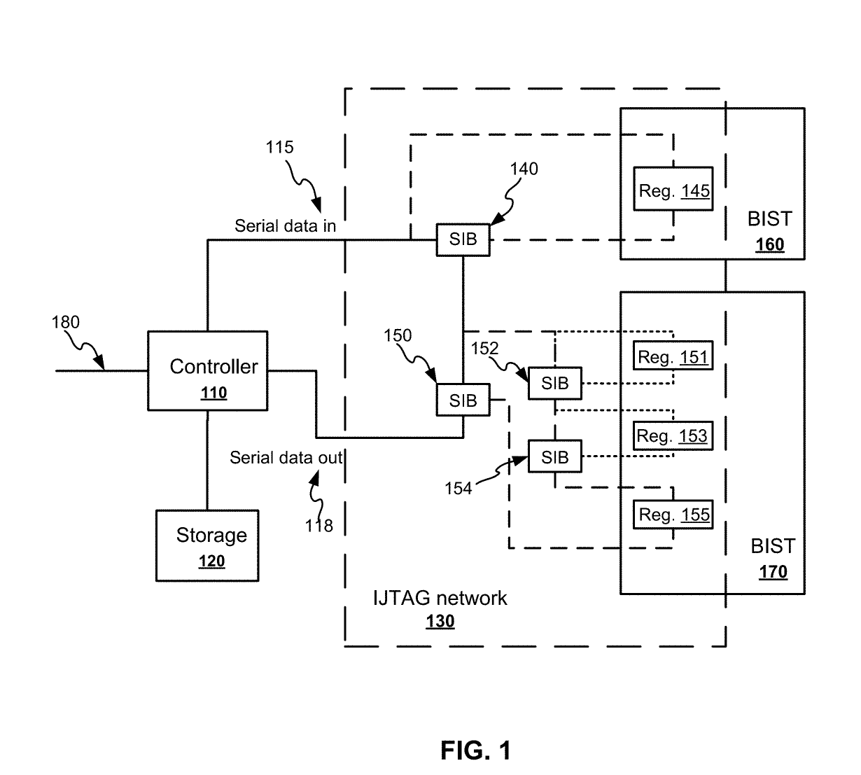

FIG. 1 illustrates an example of a block diagram of circuit architecture for in-system test according to various embodiments of the disclosed technology. The circuit comprises a controller 110, a storage device 120 and an IJTAG (IEEE 1687) network 130. The controller 110 can access test data from the storage device 120, deliver them to the IJTAG network 130 through a serial-data-in port (scan input) 115, and receive data output from the IJTAG network 130 through a serial-data-out port (scan output) 118. In a different test mode, the controller 110 delivers test data received from an interface 180 to the IJTAG network 130. One example of the different test mode is manufacturing test. In this mode, the test data may be supplied to the interface 180 by a tester using a JTAG (IEEE 1149.1) interface of the circuit. The interface 180 may be directly coupled to the TAP controller of the JTAG interface, or the IJTAG network 130 is a segment of a larger IJTAG network, which is coupled to the TAP controller of the JTAG interface.

In addition to being coupled to the serial-data-in and serial-data-out ports, the controller 110 may also supply signals to the other ports of the JTAG interface of the IJTAG network 130: Clock (TCK), Shift Enable (SE), Capture Enable (CE), Update Enable (UE), Reset (RST), and Select (EN). The first five of these signals are usually the ones from a top-level source which may be a TAP (test access port) controller or primary input ports. The Select signal is an instrument selection signal. If the IJTAG network 130 is at the top level, the Select signal may be from the TAP controller. If the IJTAG network 130 is a part of a larger IJTAG network, the Select signal may be from a higher level network element like SIB (segment insertion bit) which will be discussed in detail later. This signal helps to build a configurable hierarchical IJTAG network. Alternatively, these IJTAG interface signals may be generated by the controller 110 based on signals from internal logic.

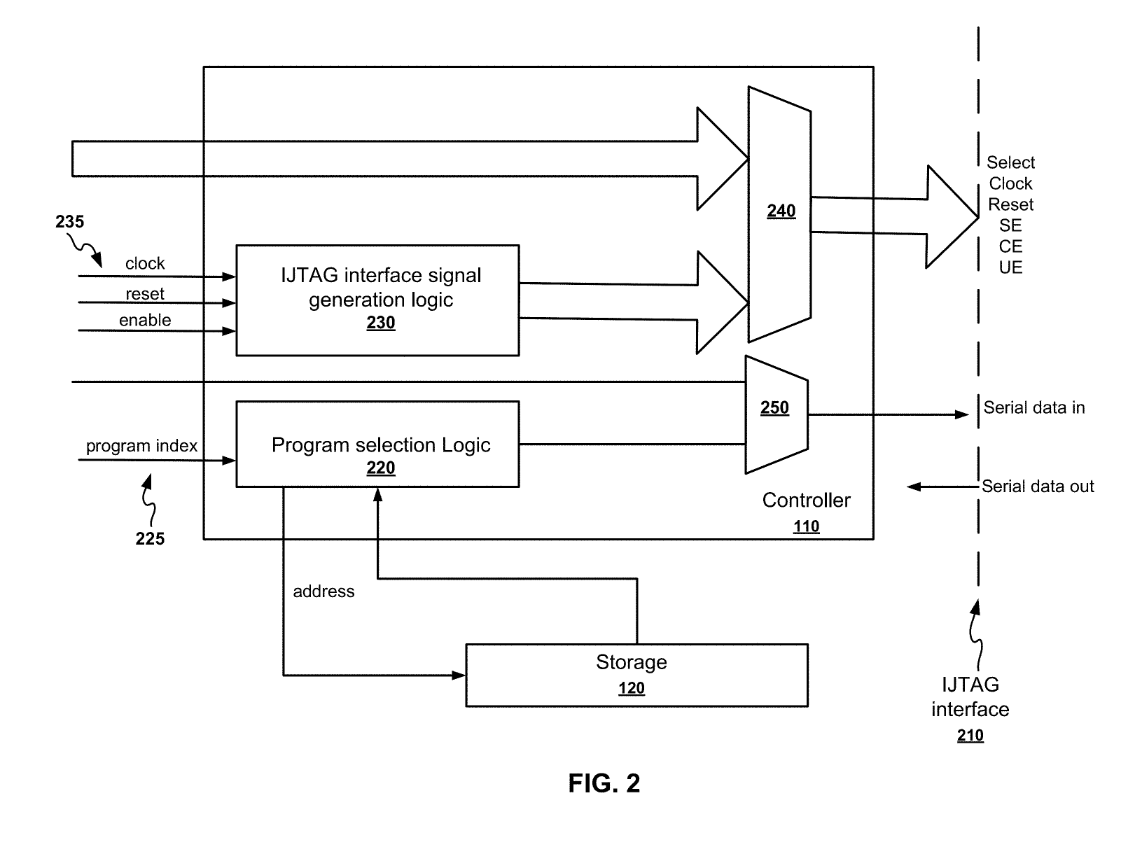

FIG. 2 illustrates an example of a block diagram of the controller 110 according to some embodiments of the disclosed technology. The controller 110 comprises program selection logic 220 and IJTAG interface signal generation logic 230. The program selection logic 220 is configured to interpret a program index signal 225 into address information for selecting test data stored in the storage device 120, to read the selected data and to supply them to the serial-data-in port of IJTAG interface 210. The IJTAG interface signal generation logic 230 is configured to generate the Clock, Shift Enable (SE), Capture Enable (CE), Update Enable (UE), Reset, and Select signals based on signals 235 (clock, reset and enable) from internal logic. While the program selection logic 220 and the IJTAG interface signal generation logic 230 are shown as separate units in the figure, a single device such as a finite state machine along with some circuitry can be used to implement them. FIG. 2 shows that the controller 110 also comprises multiplexers 240 and 250. These multiplexers allow either the signals generated by the controller 110 or from the IJTAG network at a higher level to reach the IJTAG interface 210. While the multiplexers 240 and 250 are shown as separate units in FIG. 2, a single multiplexer or more than two multiplexers may be used to implement them.

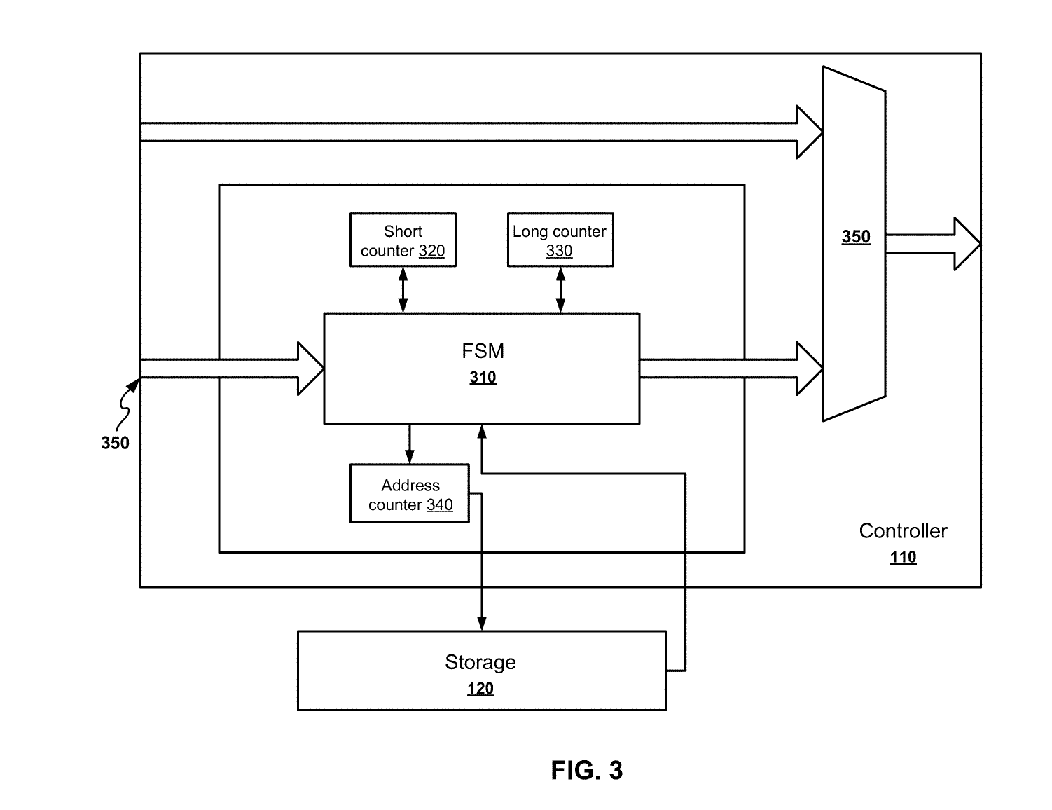

FIG. 3 illustrates another example of a block diagram of the controller 110 according to some embodiments of the disclosed technology. The controller 110 in FIG. 3 comprises a finite state machine 310 and three counters (a short counter 320, a long counter 330 and an address counter 340). The short counter 320 is used to count down from the data width to zero and is used to shift-out test data read from the storage device 120. The long counter 330 is used to count the number of words read. The long counter 330 may have a default width equal to the maximum of memory data width or address width. The long counter 330 may also be used for receiving test response data from the IJTAG interface. The finite state machine 310 generates signals for the IJTAG interface based on signals from input port 350.

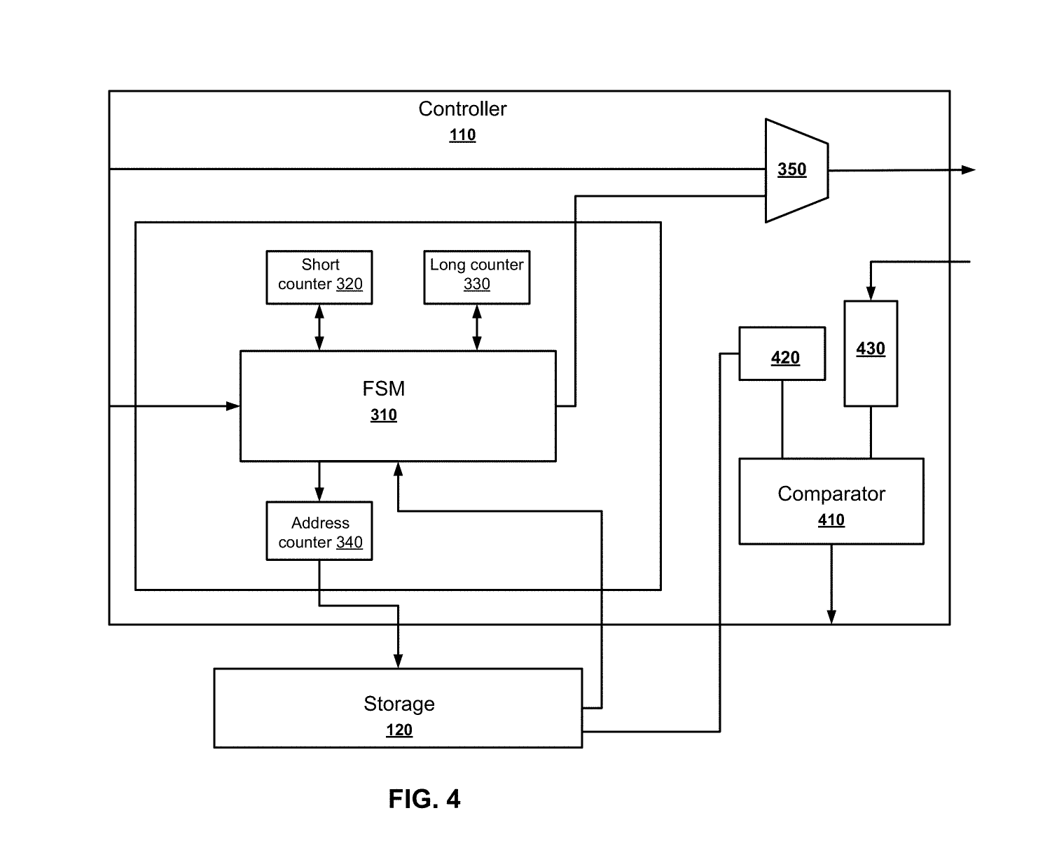

The controller 110 may further comprise circuitry for analyzing data scanned out from the serial data output port 118 shown in FIG. 1. FIG. 4 illustrates an example of a block diagram of the analysis circuitry according to various embodiments of the disclosed technology. The controller 110 in the figure comprises the same devices for generating the IJTAG interface signals as shown in FIG. 3. The analysis circuitry in the controller 110 comprises a comparator 410, an expected data register 420 and a received data register 430. The expected data register 420 temporarily stores expected data such as an expected signature from a LBIST and the received data register 430 temporarily stores shifted-out test response data such as a signature from the LBIST. The comparator may comprise logic for generating a flag signal based on comparing data from the two registers.

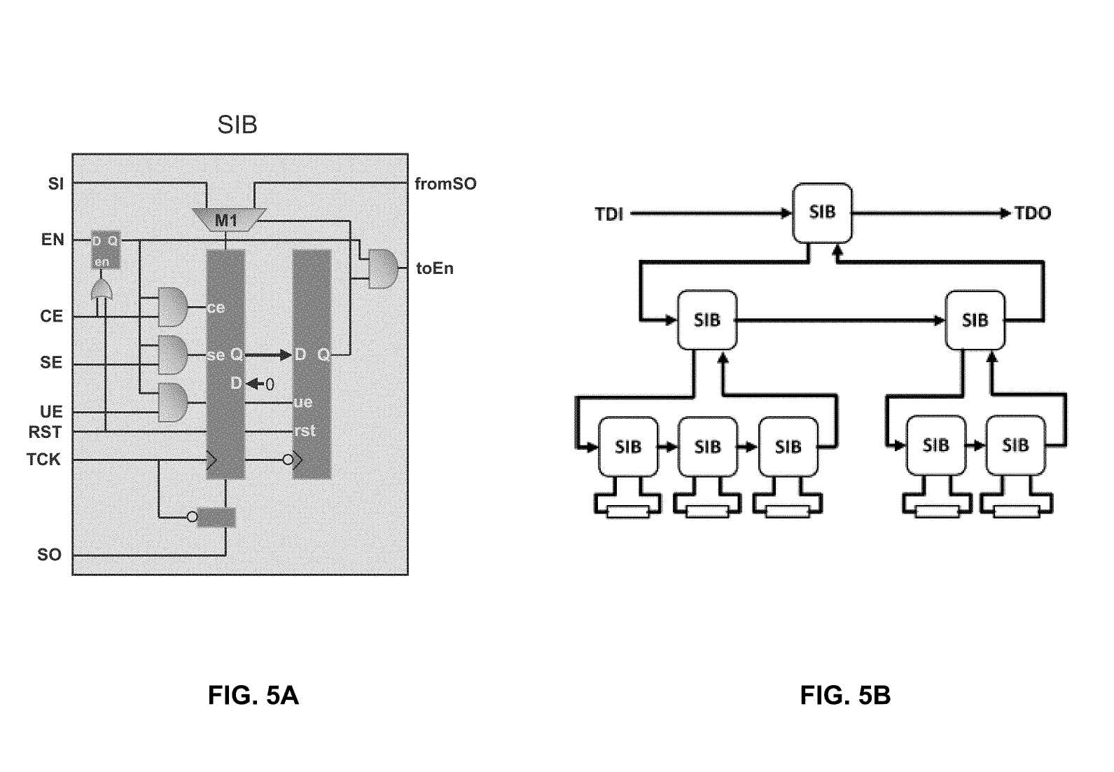

An IJTAG network is a serial scan path. The IJTAG network 130 shown in FIG. 1 includes four segment insertion bits (SIBs 140, 150, 152 and 154) and four data registers (Regs 145, 151, 153 and 155). A SIB is a 1-bit shift and update register. FIG. 5A illustrates an example of a block diagram of a SIB. SIBs can be used to dynamically configure an on-chip scan path to meet requirements of a particular set of test vectors. ‘Selecting’ a certain SIB can activate a portion of the chip's IJTAG scan path and consequently activate the instrument(s) on that segment of the scan path. Conversely, ‘de-selecting’ a SIB will deactivate a portion of the chip's overall scan path and render the instruments on that segment inaccessible. Instruments on a deactivated segment of the scan path cannot be accessed as long as the scan path segment is deactivated, but they can still execute test vectors while they are offline.

In FIG. 1, when the SIB 140 is closed, it makes a segment including the register 145 inaccessible. The register 145 is coupled to a BIST 160. As such, the BIST 160 may be inactive or performing a test while the IJTAG network 130 continues to operate. When the SIB 150 is open, the scan segment including the SIBs 152 and 154 and the register 155 is inserted into the active scan path. Whether the register 151 and the register 153 are accessible depends upon the status of the SIB 152 and the SIB 154, respectively. This may allow a BIST 170 coupled to these registers to run different test programs. The IJTAG network 130 may be coupled to a high level SIB and be a part (a segment) of a larger IJTAG network. The larger IJTAG network may comprise more segments and controllers similar to the controller 110.

Accordingly, it is possible to use SIBs to build not only a scan path of variable lengths but also a multitude of different hierarchical IJTAG networks for the same set of instruments. Hierarchical IJTAG networks with one SIB in its top level can be viewed as a directed rooted tree where the top level SIB is its root, and the instruments registers are connected to the leaves. FIG. 5B shows an example of a hierarchical SIBs network. A SIB has one parent in the higher level (except for the root), one or more children in the lower level (except for the leaves), and could have one or more siblings in the same level sharing the same parent. A SIB is selected when its parent is both selected and opened, in this case, scan control signals are also propagated from the parent SIB to its children. The root SIB is usually selected by the TAP controller. It takes time to select a SIB deep down on a hierarchical SIB tree. Accordingly, having the controller 110 close to test devices can reduce test access time.

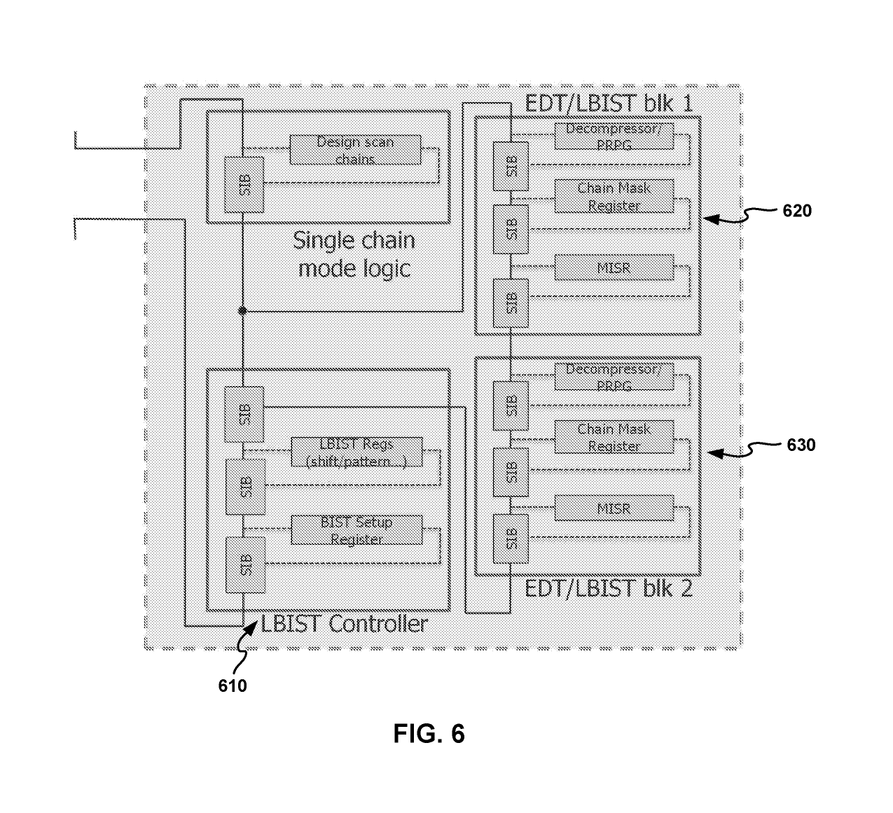

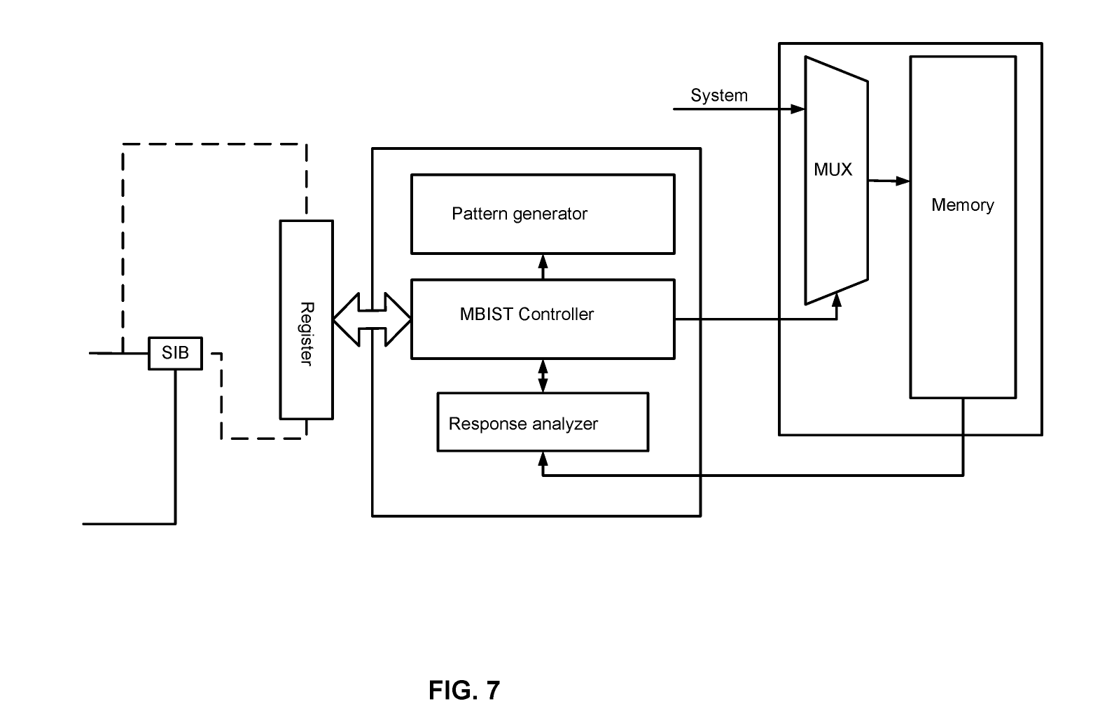

The BISTs 160 and 170 in FIG. 1 can be LBISTs or MBISTs. FIG. 6 illustrates an example of a design with a LBIST controller (610) and two EDT/LBIST blocks (620 and 630). FIG. 7 illustrates an example of a design with a MBIST. It should be noted that the IJTAG network 130 can work with a variable number of LBISTs, MBISTs and their combinations.

The storage device 120 in FIG. 1 can be a ROM (Read-only memory) or any storage mechanism can be used as long as it can be configured like a clocked synchronous memory.

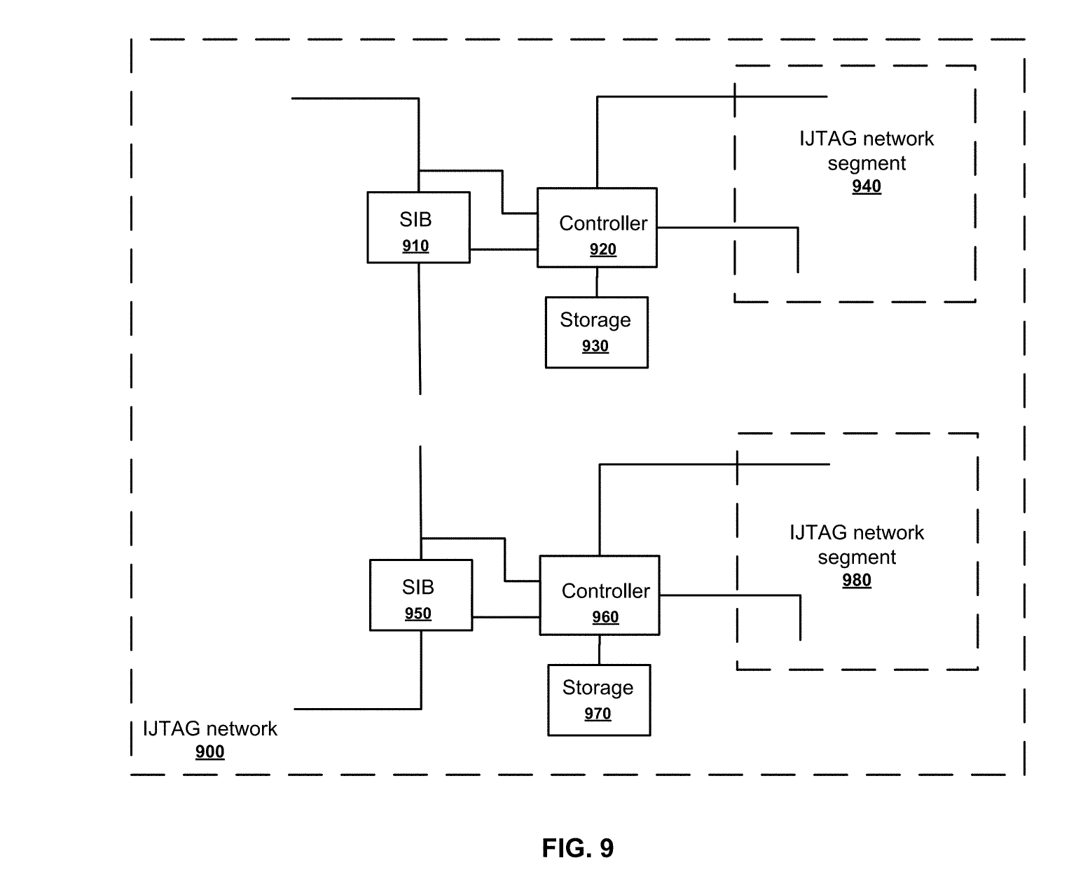

FIG. 9 illustrates an example of an IJTAG network comprising two controllers for two IJTAG segments test according to various embodiments of the disclosed technology. The IJTAG network 900 shown in the figure comprises an IJTAG network segment 940 and an IJTAG network segment 980. The accesses to these two segments are controlled by a SIB 910 and a SIB 950, respectively. Test vectors for these two segments can be scanning in through the IJTAG network 900 or be data stored locally in storage devices 930 and 970, which are controlled by controllers 920 and 960, respectively. The two IJTAG network segments 940 and 980 may be coupled directly or indirectly, on the same or different hierarchical levels of the IJTAG network 900.

It should be appreciated that the IJTAG network shown in the figures can be a single scan path or multiple parallel scan paths. It should also be appreciated that a controller according to various embodiments of the disclosed technology may allow data from an external source to be scanned in through a single scan path and data stored on chip to be scanned in through multiple scan paths in parallel.

Various examples of the disclosed technology may be implemented through the execution of software instructions by a computing device such as a programmable computer. The software instructions may be stored on a non-transitory computer-readable medium, As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

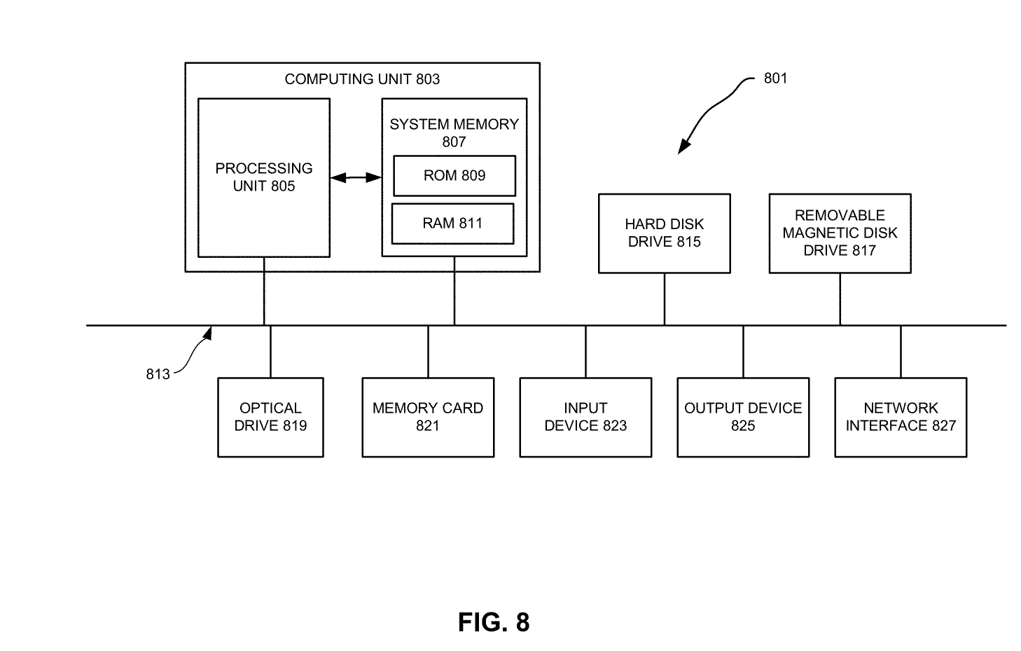

The circuit according to the disclosed technology can be generated and inserted into a circuit design through the execution of software instructions. FIG. 8 shows an illustrative example of a computing device 801 that may be used for through the execution of software instructions. As seen in this figure, the computing device 801 includes a computing unit 803 with a processing unit 805 and a system memory 807. The processing unit 805 may be any type of programmable electronic device for executing software instructions, but will conventionally be a microprocessor. The system memory 807 may include both a read-only memory (ROM) 809 and a random access memory (RAM) 811. As will be appreciated by those of ordinary skill in the art, both the read-only memory (ROM) 809 and the random access memory (RAM) 811 may store software instructions for execution by the processing unit 805.

The processing unit 805 and the system memory 807 are connected, either directly or indirectly, through a bus 813 or alternate communication structure, to one or more peripheral devices. For example, the processing unit 805 or the system memory 807 may be directly or indirectly connected to one or more additional memory storage devices, such as a “hard” magnetic disk drive 815, a removable magnetic disk drive 817, an optical disk drive 819, or a flash memory card 821. The processing unit 805 and the system memory 807 also may be directly or indirectly connected to one or more input devices 823 and one or more output devices 825. The input devices 823 may include, for example, a keyboard, a pointing device (such as a mouse, touchpad, stylus, trackball, or joystick), a scanner, a camera, and a microphone. The output devices 825 may include, for example, a monitor display, a printer and speakers. With various examples of the computer 801, one or more of the peripheral devices 815-825 may be internally housed with the computing unit 803. Alternately, one or more of the peripheral devices 815-825 may be external to the housing for the computing unit 803 and connected to the bus 813 through, for example, a Universal Serial Bus (USB) connection.

With some implementations, the computing unit 803 may be directly or indirectly connected to one or more network interfaces 827 for communicating with other devices making up a network. The network interface 827 translates data and control signals from the computing unit 803 into network messages according to one or more communication protocols, such as the transmission control protocol (TCP) and the Internet protocol (IP). Also, the interface 827 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computer 801 is illustrated as an example only, and it not intended to be limiting. Various embodiments of the disclosed technology may be implemented using one or more computing devices that include the components of the computer 801 illustrated in FIG. 8, which include only a subset of the components illustrated in FIG. 8, or which include an alternate combination of components, including components that are not shown in FIG. 8. For example, various embodiments of the disclosed technology may be implemented using a multi-processor computer, a plurality of single and/or multiprocessor computers arranged into a network, or some combination of both.

### CONCLUSION

While the disclosed techniques has been described with respect to specific examples including presently preferred modes of carrying out the disclosed techniques, those skilled in the art will appreciate that there are numerous variations and permutations of the above described systems and techniques that fall within the spirit and scope of the disclosed techniques as set forth in the appended claims. For example, while specific terminology has been employed above to refer to electronic design automation processes, it should be appreciated that various examples of the disclosed techniques may be implemented using any desired combination of electronic design automation processes.

What is claimed is:

1. An integrated circuit, comprising:
a plurality of built-in self-test circuits;
a plurality of SIBs (segment insertion bits) coupled to a plurality of registers associated with the plurality of built-in self-test circuits, the plurality of SIBs and the plurality of registers forming a part or a whole of an IJTAG (IEEE 1687) network;
one or more storage devices; and
a controller coupled to the part or the whole of the IJTAG network and to the one or more storage devices, wherein the controller supplies to the part or the whole of the IJTAG network test vectors which are stored in the one or more storage devices or are received from a different source.

2. The integrated circuit recited in claim 1, wherein the different source is a tester.

3. The integrated circuit recited in claim 2, wherein the tester delivers the test vectors to the integrated circuit through a JTAG (IEEE 1149.1) interface of the integrated circuit.

4. The integrated circuit recited in claim 1, wherein the plurality of built-in self-test circuits comprise logic built-in self-test circuits (LBIST), memory built-in self-test circuits (MBIST) or both.

5. The integrated circuit recited in claim 1, wherein the one or more storage devices is a read-only memory device.

6. The integrated circuit recited in claim 1, wherein the controller comprises logic circuitry for generating IJTAG interface signals based on input signals.

7. The integrated circuit recited in claim 1, wherein the controller comprises a finite state machine.

8. The integrated circuit recited in claim 1, wherein the one or more storage devices further store expected test response data and the controller comprises logic circuitry for comparing test response data received from the IJTAG network with the expected test response data.

9. The integrated circuit recited in claim 1, further comprising:
a second plurality of built-in self-test circuits;
a second plurality of SIBs (segment insertion bits) coupled to a second plurality of registers associated with the second plurality of built-in self-test circuits, the second plurality of SIBs and the second plurality of registers forming a second part of the IJTAG network;
second one or more storage devices; and
a second controller coupled to the second part of the IJTAG network and to the second one or more storage devices, wherein the second controller supplies to the second part of the IJTAG network test vectors which are stored in the second one or more storage devices or are received from the different source.

10. One or more non-transitory computer-readable media storing computer-executable instructions for causing one or more processors to insert circuitry into a circuit design, the circuitry comprising:
a controller coupled to a part or a whole of an IJTAG network and to one or more storage devices, wherein the part or the whole of the IJTAG network comprises a plurality of SIBs and a plurality of registers associated with a plurality of built-in self-test circuits, and wherein the controller supplies to the part or the whole of the IJTAG network test vectors which are stored in the one or more storage devices or are received from a different source.

11. The one or more non-transitory computer-readable media recited in claim 10, wherein the different source is a tester.

12. The one or more non-transitory computer-readable media recited in claim 11, the tester delivers the test vectors to the integrated circuit through a JTAG (IEEE 1149.1) interface of the integrated circuit.

13. The one or more non-transitory computer-readable media recited in claim 10, wherein the plurality of built-in self-test circuits comprise logic built-in self-test circuits (LBIST), memory built-in self-test circuits (MBIST) or both.

14. The one or more non-transitory computer-readable media recited in claim 10, wherein the one or more storage devices is a read-only memory device.

15. The one or more non-transitory computer-readable media recited in claim 10, wherein the controller comprises logic circuitry for generating IJTAG interface signals based on input signals.

16. The one or more non-transitory computer-readable media recited in claim 10, wherein the controller comprises a finite state machine.

17. The one or more non-transitory computer-readable media recited in claim 10, wherein the one or more storage devices further store expected test response data and the controller comprises logic circuitry for comparing test response data received from the IJTAG network with the expected test response data.

18. The one or more non-transitory computer-readable media recited in claim 10, wherein the circuitry further comprises:
a second controller coupled to a second part of the IJTAG network and to second one or more storage devices, wherein the second part of the IJTAG network comprises a second plurality of SIBs and a second plurality of registers associated with a second plurality of built-in self-test circuits, and wherein the second controller supplies to the second part of the IJTAG network test vectors which are stored in the second one or more storage devices or are received from the different source.
